(19) United States
(12) Patent Application Publication
(10) Pub. No.: US 2015/0073581 A1
(43) Pub. Date: Mar. 12, 2015

(54) SYSTEM FOR REDUCING ENERGY CONSUMPTION AND FRACTION DEFECTIVE WHEN PRODUCING PCB BASED ON UBIQUITOUS SENSOR NETWORK

(71) Applicant: Advanced Consulting Services Corp., Seoul (KR)

(72) Inventors: Suk Keun CHA, Seoul (KR); Gyu Bong LEE, Seongnam-si (KR)

(73) Assignee: Advanced Consulting Services Corp., Seoul (KR)

(21) Appl. No.: 14/024,293

(22) Filed: Sep. 11, 2013

(51) Int. Cl. H01L 21/02

(52) U.S. Cl. CPC H01L 21/02
USPC 700/121

(57) ABSTRACT

Provided is a system for reducing energy consumption and fraction defective when producing a PCB based on a USN, which provides the optimal environment information in PCB production by acquiring, accumulating, and analyzing the environment information in each process when producing the PCB. The system includes a sensor node unit to acquire environment information of a production facility and wirelessly transmit the environment information, a data collection unit to collect the environment information transmitted from the sensor node unit and transmit the environment information through a TCP/IP, an environment information generation unit to receive the environment information, accumulate and store the environment information according to types of PCBs and production facilities, analyze environment information based on the accumulated environment information to generate optimal environment information, and an environment information providing unit to form the optimal environment information as information to be recognized by a user and display the information.

### BACKGROUND OF THE INVENTION

1. Field of the Invention

The present invention relates to a system for reducing energy consumption and fraction defective when producing a printed circuit board (PCB) based on a ubiquitous sensor network (USN). In particular, the present invention relates to a system for reducing energy consumption and fraction defective when producing a PCB based on a USN, capable of acquiring, accumulating, and analyzing environment information in each process when producing the PCB to provide process environment information optimized with respect to PCB production.

2. Description of the Related Art

In general, a process of producing a printed circuit board (PCB) may be varied depending on companies for producing the PCBs . Typically, the PCB may be produced by performing a copper clad laminate (CCL) cutting process using a cutter, an inner layer working process, a lamination process, a shaping process by using a shaper, a tapping stacking process, a drill process of machining a hole, a high-pressure cleaning process using a cleaning machine, a desmear process, a panel plating process, pickling and scrubbing processes to make the surface of a copper clad rough, a bonding process, a pattern exposure process, a D/F developing process, an etching process, a D/F delamination process, a PSR scrubbing process, a PSR printing process, a PSR drying process, a PSR exposure process, a PSR developing process, a marking process to print and dry invariable ink, a surface treatment process, a router process, a V-cut process, a cleaning process, a BBT process, and an inspecting process for the quality management.

In this case, a PCB, which is a production target, is transferred to a position for each process through a conveyer in each process.

According to the typical PCB production process, the fraction defective and the energy consumption occurring in the PCB process production may be varied depending on environment information (speed, amount of consumed electric power, time, temperature, amount of used water, etc.) provided in each process. According to the related art, the production situation is simply determined based on the total energy consumption and the total power consumption without monitoring the environment information for each process.

However, it is insufficient to optimally analyze PCB production efficiency by using only the total energy consumption and the total power consumption. For example, although various environments are provided in the PCB production process, it is difficult to analyze the PCB production efficiency by simply using the total energy consumption and the total power consumption without precisely analyzing the environments.

Accordingly, there have been suggested various methods to enhance production efficiency by monitoring the environment information required in a specific production process and adjusting required energy based on the monitoring result, and one of them is disclosed in Korean Patent Registration No. 10-0918923 (issued on Sep. 28, 2009) which is titled “the apparatus and method of smart energy control in ubiquitous sensor network” (hereinafter, related art).

According to the disclosed related art, a ubiquitous sensor network reference node embedded therein with a temperature sensor, a humidity sensor, and an infrared sensor is installed in a specific place such as an industrial site, and a main controller and a main server are connected to the ubiquitous sensor network reference node through a wireless communication network based on ZigBee, WiFi, or Bluetooth, thereby enhancing power usage efficiency by monitoring and controlling illuminance, humidity, temperature, and power through the wireless communication network.

However, according to the PCB production method, the environment information required in each process cannot be exactly monitored. Accordingly, the environment information used to enhance the PCB production efficiency cannot be provided.

In addition, according to the related art, slight efficiency may be represented in power control. However, although various pieces of environment information exists in the industrial site, the monitoring and controlling of the various environment information are impossible, and only simple power control is performed.

### SUMMARY OF THE INVENTION

Therefore, the present invention is suggested to solve problems occurring in the typical PCB production process and the related art.

An object of the present invention is to provide a system for reducing energy consumption and fraction defective when producing a printed circuit board (PCB) based on a ubiquitous sensor network (USN), capable of providing the optimal environment information in PCB production by acquiring, accumulating, and analyzing the environment information in each process when producing a PCB.

Another object of the present invention is to provide a system for reducing energy consumption and fraction defective when producing a printed circuit board (PCB) based on a ubiquitous sensor network (USN), capable of reducing energy consumption and minimizing fraction defective when producing the PCB by providing the optimal environment information in PCB production.

Still another object of the present invention is to provide a system for reducing energy consumption and fraction defective when producing a printed circuit board (PCB) based on a ubiquitous sensor network (USN), capable of easily acquiring the conveyer speed, an amount of consumed electric power, an amount of used water, and drying machine temperature information in relation to each process by installing a USN sensor node in the production process to schematically monitor the energy in each process and analyze the energy, so that the optimal energy (environment information) in each process can be provided.

In order to accomplish the above objects, there is provided a system for reducing energy consumption and fraction defective when producing a printed circuit board (PCB) based on a ubiquitous sensor network (USN). The system includes a sensor node unit provided in a production facility for the PCB to acquire environment information of the production facility and wirelessly transmit the acquired environment information, a data collection unit to collect the environment information transmitted from the sensor node unit and transmit the collected environment information through an Internet standard protocol (TCP/IP), an environment information generation unit to receive the environment information transmitted from the data collection unit through the TCP/IP, accumulate and store the received environment information according to types of PCBs and production facilities, analyze environment information based on the accumulated environment information, such that optimal environment information is generated to reduce the energy consumption and minimize the fraction defective, and an environment information providing unit to form the optimal environment information, which is generated from the environment information generation unit, as information to be recognized by a user and display the information to be recognized by the user.

The sensor node unit includes a first sensor node to acquire environment information of a cleaning machine, which is used in a cleaning process, among the production facilities for the PCB.

The sensor node unit includes a second sensor node to acquire environment information of a drying machine, which is used in a drying process, among the production facilities for the PCB.

The sensor node unit includes a third sensor node to acquire environment information of an inspecting machine, which is used in an inspecting process, among the production facilities for the PCB.

The sensor node unit includes a fourth sensor node to acquire environment information of a conveyer facility to transfer a PCB to be produced in the cleaning process, the drying process, and the inspecting process.

The first sensor node includes a sensor unit including an inverter to measure an amount of water used in the cleaning machine and a hydraulic pressure of the water and a turbidimeter to measure turbidity of the water used in the cleaning machine, a storage unit to store an identification address used to identify the cleaning machine and store information of an amount of the used water, a hydraulic pressure of the water, and turbidity of the water which are measured, and a communication unit to insert the identification address, which is stored in the storage unit, into a header of a packet and insert the information of the amount of the used water, the hydraulic pressure of the water, and the turbidity of the water into a specific position of the packet to form the packet and wirelessly transmit the packet.

The second sensor node includes a sensor unit including a watt-hour meter to measure the amount of electric power consumed by the drying machine and a thermometer to measure a temperature of the drying machine, a storage unit to store an identification address to identify the drying machine and store information of the amount of electric power and a temperature that are measured, and a communication unit to insert the identification address, which is stored in the storage unit, into a header of a packet and insert information of the amount of electric power and the temperature into a specific position of the packet to form the packet and wirelessly transmit the packet.

The third sensor node includes a sensor unit including a production detection unit cooperating with the inspection machine to measure the production of the PCB and a defect inspection unit cooperating with the inspection machine to measure the fraction defective, a storage unit to store an identification address to identify the inspecting machine and store information of the production of the PCB and the fraction defective that are measured, and a communication unit to insert the identification address, which is stored in the storage unit, into a header of a packet and insert information of the production of the PCB and information of the fraction defective into a specific position of the packet to form the packet and wirelessly transmit the packet.

The fourth sensor node includes a sensor unit including a wattmeter to measure the amount of electric power consumed by the conveyer facility and a speedometer to measure a speed of the conveyer facility, a storage unit to store an identification address to identify the conveyer facility and store information of the amount of electric power and the speed of the conveyer facility that are measured, and a communication unit to insert the identification address, which is stored in the storage unit, into a header of a packet and insert the information of the amount of electric power and the speed of the conveyer facility into a specific position of the packet to form the packet and wirelessly transmit the packet.

The data collection unit is implemented in the form of a machine-to-machine (M2M) device.

The environment information generation unit includes a middle-ware (M/W), and the middle-ware includes a communication manager to collect the environment information in each process when producing the PCB through the data collection unit in real time, a tag manager serving as a real-time interface with respect to the environment information acquired from the communication manager, a real-time data manager to store the environment information, which is acquired from the tag manager in real time, in a database, and store even environment information, which is provided after analysis, in the database, and an environment application manager to generate optimal environment information to reduce energy consumption and minimize fraction defective by analyzing the environment information provided from the tag manager according to the types of the PCBs and the production facilities.

As described above, according to the present invention, the optimal environment information can be provided in PCB production by acquiring, accumulating, and analyzing the environment information in each process when producing a PCB.

Further, according to the present invention, energy consumption can be reduced and fraction defective can be minimized when producing the PCB by providing the optimal environment information in PCB production.

In addition, according to the present invention, the conveyer speed, an amount of consumed electric power, an amount of used water, and drying machine temperature information can be easily acquired in relation to each process by installing a USN sensor node in the production process to schematically monitor the energy in each process and analyze the energy, so that the optimal energy (environment information) in each process can be provided.

### BRIEF DESCRIPTION OF THE DRAWINGS

FIG. 1 is a block diagram showing a system for reducing energy consumption and fraction defective when producing a PCB based on a ubiquitous sensor network according to the present invention.

FIG. 2 is a block diagram showing a first sensor node of FIG. 1 according to the embodiment of the present invention.

FIG. 3 is a block diagram showing a second sensor node of FIG. 1 according to the embodiment of the present invention.

FIG. 4 is a block diagram showing a third sensor node of FIG. 1 according to the embodiment of the present invention.

FIG. 5 is a block diagram showing a fourth sensor node of FIG. 1 according to the embodiment of the present invention.

FIG. 6 is a block diagram showing an environment information generation unit of FIG. 1 according to the embodiment of the present invention.

### DETAILED DESCRIPTION OF THE INVENTION

Hereinafter, example embodiments of the present invention will be described in detail with reference to accompanying drawings. In addition, the details of the generally known function and structure, which make the subject matter of the embodiment unclear, will be omitted.

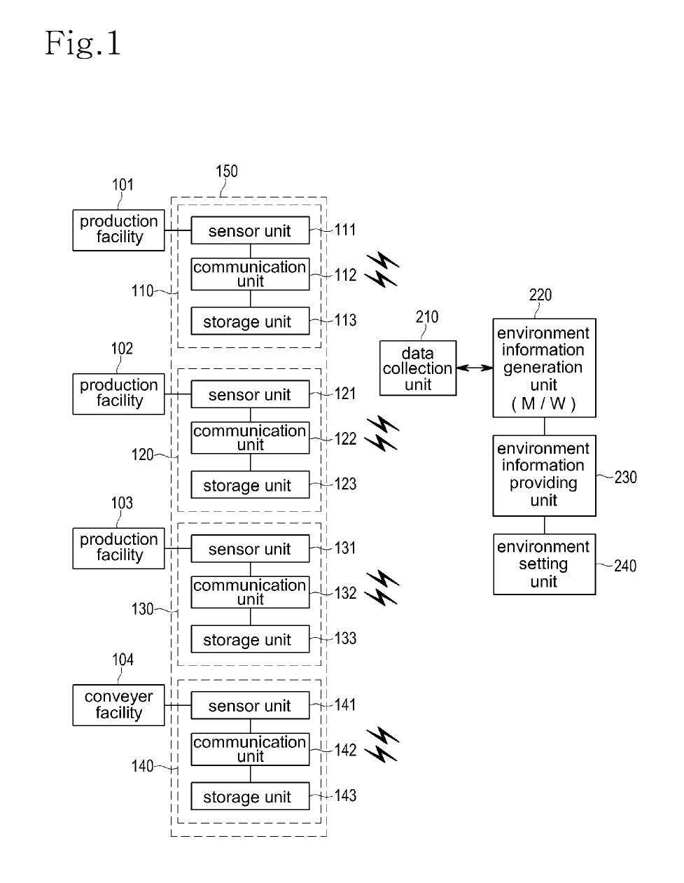

FIG. 1 is a block diagram showing a system for reducing energy consumption and fraction defective when producing a PCB based on a ubiquitous sensor network according to the present invention, which includes production facilities 101 to 104, sensor node units 150, a data collection unit 210, an environment information generation unit 220, an environment information providing unit 230, and an environment setting unit 240. In this case, the sensor node units 150 are installed in the production facilities 101 to 104, and the data collection unit 210, the environment information generation unit 220, the environment information providing unit 230, and the environment setting unit 240 are installed in places remote from the sensor node units 150.

The production facilities 101 to 104 are provided for production processes when producing a printed circuit board (PCB). Although environment information may be collected and analyzed in the whole PCB production process according to the present invention, description will be made in that the environment information may be collected and analyzed only with respect to a cleaning process, a drying process, an inspecting process, and a conveyer facility according to the embodiment for the convenience of explanation.

The sensor node units 150 are provided in the production facilities 101 to 104 for the PCB to acquire environment information of the corresponding production facilities and wirelessly transmit the acquired environment information.

The sensor node unit 150 includes a first sensor node 110 to acquire the environment information of a cleaning machine, which is used in the cleaning process, among the production facilities for the PCB, a second sensor node 120 to acquire the environment information of a drying machine, which is used in the drying process, among the production facilities for the PCB, a third sensor node 130 to acquire the environment information acquired by an inspecting machine, which is used in the inspecting process, among the production facilities for the PCB, and a fourth sensor node 140 to acquire the environment information of a conveyer facility to transfer a PCB to be produced in the cleaning process, the drying process, and the inspecting process.

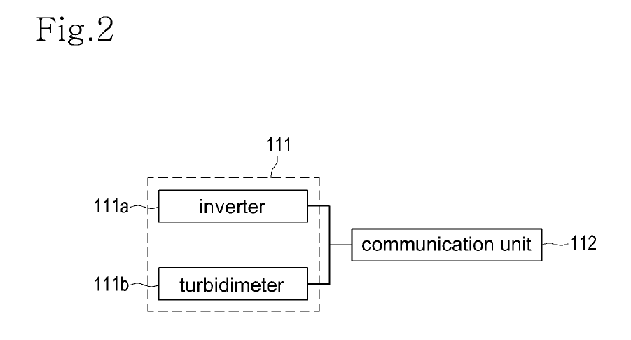

Preferably, as shown in FIG. 2, the first sensor node 110 includes a sensor unit 111 including an inverter 111a to measure an amount of water used in the cleaning machine and the hydraulic pressure of the water and a turbidimeter 111b to measure the turbidity of the water used in the cleaning machine, a storage unit 113 to store an identification address used to identify the cleaning machine and store the information of the amount of the used water, the hydraulic pressure of the water, and the turbidity of the water that are measured, and a communication unit 112 to insert the identification address, which is stored in the storage unit 113, into a header of a packet and insert the information of the amount of the used water, the hydraulic pressure of the water, and the turbidity of the water into a specific position of the packet to form the packet and wirelessly transmit the packet.

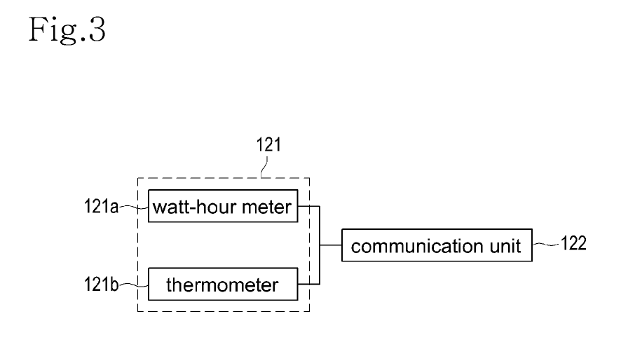

More particularly, as shown in FIG. 3, the second sensor node 120 includes a sensor unit 121 including a watt-hour meter 121a to measure the amount of electric power consumed by the drying machine and a thermometer 121b to measure the temperature of the drying machine, a storage unit 123 to store an identification address used to identify the drying machine and store the information of the amount of consumed electric power and the temperature that are measured, and a communication unit 122 to insert the identification address, which is stored in the storage unit 123, into a header of a packet and insert the information of the amount of consumed electric power and the temperature into a specific position of the packet to form the packet and wirelessly transmit the packet.

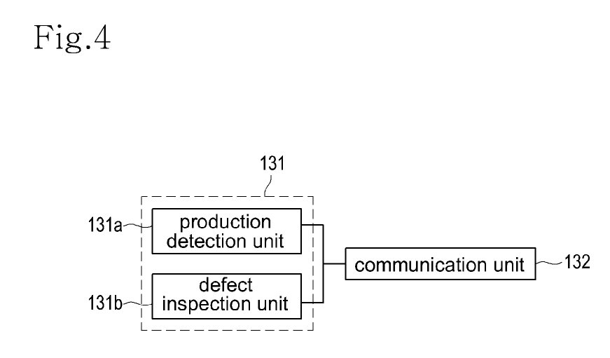

More particularly, as shown in FIG. 4, the third sensor node 130 includes a sensor unit 131 including a production detection unit 131a cooperating with the inspection machine to measure the production of the PCB and a defect inspection unit 131b cooperating with the inspection machine to measure the fraction defective, a storage unit 133 to store an identification address to identify the inspecting machine and store the information of the production of the PCB and the fraction defective that are measured, and a communication unit 132 to insert the identification address, which is stored in the storage unit 133, into a header of a packet and insert the information of the production of the PCB and the information of the fraction defective into a specific position of the packet to form the packet and wirelessly transmit the packet.

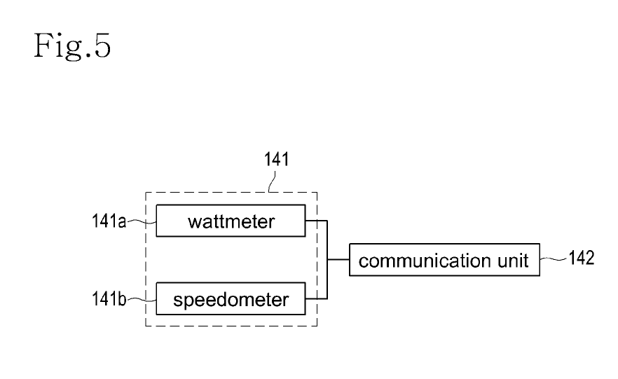

More particularly, as shown in FIG. 5, the fourth sensor node 140 includes a sensor unit 141 including a wattmeter 141a to measure the amount of electric power consumed by the conveyer facility 104 and a speedometer 141b to measure the speed of the conveyer facility 104, a storage unit 143 to store an identification address to identify the conveyer facility 104 and store the information of the amount of consumed electric power and the speed that are measured, and a communication unit 142 to insert the identification address, which is stored in the storage unit 143, into a header of a packet and insert the information of the amount of consumed electric power and the speed of the conveyer facility into a specific position of the packet to form the packet and wirelessly transmit the packet.

The data collection unit 210 collects the environment information transmitted from the sensor node unit 150 and transmits the collected environment information through the TCP/IP. The data collection unit 210 is preferably implemented in the form of an M2M (machine to machine) device.

The environment information generation unit 220 receives the environment information transmitted from the data collection unit 210 through the TCP/IP, accumulates and stores the received environment information according to the types of PCBs and the production facilities, and analyzes the environment information based on the accumulated environment information, thereby generating the optimal environment information to reduce energy consumption and minimize the fraction defective.

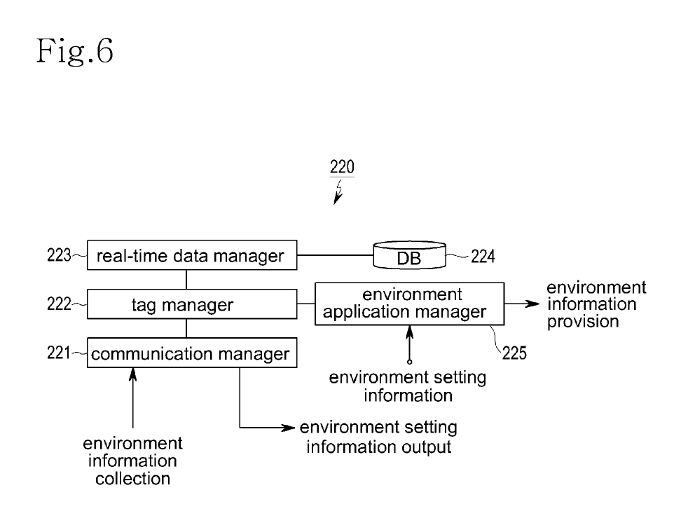

The environment information generation unit 220 includes a middleware (M/W). As shown in FIG. 6, the M/W includes a communication manager 221 to collect the environment information in each process when producing the PCB through the data collection unit 210 in real time, a tag manager 222 serving as a real-time interface with respect to the environment information acquired from the communication manager 221, a real-time data manager 223 to store the environment information, which is acquired from the tag manager 222 in real time, in a database 224, and store even environment information, which is provided after analysis, in the database 224, and an environment application manager 225 to analyze the environment information provided from the tag manager 222 according to the types of the PCBs and the production facilities, thereby generating the optimal environment information to reduce energy consumption and minimize the fraction defective.

The environment information providing unit 230 forms the optimal environment information generated from the environment information generation unit 220 as information that can be recognized by a user and displays the information . The environment information providing unit 230 is preferably implemented in the form of a display device such as a liquid crystal display (LCD).

In addition, the environment setting unit 240 allows a user to manually set up the optimal conveyer speed and the optimal temperature based on the environment information displayed on the environment information providing unit 230. The environment setting unit 240 includes an input device such as a typical keypad or a typical key board.

The system for reducing energy consumption and fraction defective when producing the PCB based on the ubiquitous sensor network according to the present invention as configured above includes production facilities (e.g., production facilities 101 to 104 in the cleaning process, the drying process, the inspecting process, or the conveyer facility) to schematically monitor energy during the process of producing the PCB and the sensor node unit 150 including the first to fourth sensor nodes 110 to 140 to acquire the environment information which is installed in the production facilities.

In this case, the environment information refers to all kinds of energy required in the cleaning process, the drying process, the inspecting process, and the conveyer facility. The environment information includes information of water, the information of the turbidity of the water, the information of electric power, the information of a temperature, the information of a conveyer speed, the information of the production of PCBs, and the information of the fraction defective.

Thereafter, target information to reduce the energy and the fraction defective is set, and the setting of the target information refers to setting of the type of the PCB. In general, there are various types of PCBs. When the information of the types of the PCBs is previously registered, the type of the PCB, which is currently produced, may be recognized. For example, the environment information may be varied depending on the types of the PCBs. In order to provide the exact environment information according to the type of the PCB, the type of the PCB may be set.

The first sensor node 110 is installed in the cleaning machine, which is the production facility 101 provided for the cleaning process, among the PCB production facilities. In this case, the sensor unit 111 of the first sensor node 110 measures the amount of the water used in the cleaning machine by using the inverter 111a, and measures the turbidity of the water used for the cleaning process in the cleaning machine by using the turbidimeter 111b. The measured information of the turbidity is used as information to determine the time to replace the water used in the cleaning machine thereafter.

The communication unit 112 stores the information of the amount of the used water and the information of the turbidity of the water, which are measured, in the storage unit 113 while extracting the identification address to distinguish the cleaning machine stored in the storage unit 113. Then, the communication unit 112 generates a packet by employing the extracted identification address as header information and the information of the amount of used water and the information of the turbidity of the water as payload information. The packet containing the environment information of the cleaning process, which is generated in such a manner, is made and transmitted through a wireless scheme (e.g., ZigBee, WiFi, Bluetooth, etc.).

In addition, the second sensor node 120 is installed in the drying machine, which is the production facility 102 provided for the drying process, among the PCB production facilities. In this case, the sensor unit 121 of the second sensor node 120 measures power consumption in the drying machine by using the watt-hour meter 121a, and measures the temperature of the drying machine by using the thermometer 121b. The measured information of the temperature is used to analyze temperature variation.

The communication unit 122 stores the information of the amount of consumed electric power and the temperature, which are measured, in the storage unit 123 while extracting the identification address to distinguish drying machine stored in the storage unit 123. Then, the communication unit 112 generates a packet by employing the extracted identification address as header information and the stored information of the power consumption and the temperature as payload information. The packet containing the environment information of the drying process, which is generated in such a manner, is made and transmitted through a wireless scheme (e.g., ZigBee, WiFi, Bluetooth, etc.).

Further, the third sensor node 130 is installed in the production facility 103 provided for the drying process among the PCB production facilities. In this case, the sensor unit 131 of the third sensor node 130 measures the production of the PCBs by using the production detection unit 131a, and measures the fraction defective of the produced PCB by using the defect inspection unit 131b.

The communication unit 132 stores the information of the production of the PCBs and the information of the fraction defective of the PCBs, which are measured, in the storage unit 133 while extracting the identification address to distinguish the inspecting process production facility stored in the storage unit 133. Then, the communication unit 112 generates a packet by employing the extracted identification address as header information and the stored information of the amount of consumed electric power and the stored information of the temperature as payload information. The packet containing the environment information of the production of the PCBs and the environment information of the fraction defective, which are generated in such a manner, is made and transmitted through a wireless scheme (e.g., ZigBee, WiFi, Bluetooth, etc.).

The fourth sensor node 140 is installed in the production facility 104 which is a conveyer facility among the PCB production facilities. In this case, the sensor unit 141 provided in the fourth sensor node 140 measures the amount of electric power required in the conveyer by using the wattmeter 141a and measures the speed of the conveyer by using the speedometer 141b.

The communication unit 142 stores the information of the amount of electric power and the speed, which are measured, in the storage unit 143 while extracting the identification address to distinguish a conveyer facility stored in the storage unit 143. Then, the communication unit 142 generates a packet by employing the extracted identification address as header information and the stored information of the amount of electric power and the stored information of the speed as payload information. The packet containing the environment information of the drying process, which are generated in such a manner, is made and transmitted through a wireless scheme (e.g., ZigBee, WiFi, Bluetooth, etc.).

The data collection unit 210 collects the environment information, which is transmitted from each production facility, through the M2M device. The data collecting unit 210 transmits the collected environment information to the environment information generation unit 220 based on the TCP/IP.

In this case, the TCP/IP is a protocol system for data communication between computers. According to the TCP/IP, when a message is exchanged between computers, the message is divided in a proper size and transmitted so that errors do not occur in the message, and the transmitted message is recovered to an original message. The TCP/IP is a compound word of the TCP and the IP performing the most important functions among Internet protocols. The TCP/IP is a communication protocol forming a core of the Internet operation, and performs the management of data flow and the checking for data accuracy (the function of the TCP) and the transmission of a packet to a destination (the function of the IP).

In general, the IP exactly transfers data from one place to another place, and the TCP adjusts data flow so that full data can be smoothly transferred, and ensures the data flow so that the data can successfully arrive at a computer of the counterpart. The TCP/IP is the standard of an open-type protocol, and can be independently used in a specific hardware or a specific operating system (OS). In addition, the TCP/IP is a protocol to connect computers having different systems over the Internet to each other and transmit data therebetween and used for both of short-range communication and far-distance communication.

The TCP/IP includes four layers of an application layer, a transport layer, an Internet layer, and a network interface layer. The application layer receives a request from a user application program, transforms the request into a proper message, and sends the transformed message to a lower layer. The transport layer performs a control operation such as the check for the error of the packet transferred through the IP and the request for the retransmission of the packet, and includes two protocols of TCP and UDP. Further, the Internet layer controls only the effective transmission of the packet received therein from the transport layer to a destination. Lastly, the network interface layer supports all standards and all technical protocols without defining a specific protocol. The network interface layer uploads a frame onto a physical line or downloads the frame from the physical line.

The environment information generation unit 220 generates environment information to produce the optimal PCB to reduce energy consumption and minimize the fraction defective by storing and analyzing environment information which is acquired in a corresponding process when producing a PCB and received based on the TCP/IP.

In other words, as shown in FIG. 6, the environment information generation unit 220 is implemented in middle ware.

In the environment information generation unit 220, the communication manager 221 collects the environment information generated in each process when producing the PCB through the data collection unit 210 in real time.

Further, the tag manager 222 serves as a real-time interface between the real-time data manager 223 and the environment application manager 225 with respect to the environment information acquired from the communication manager 221.

The real-time data manager 223 stores the environment information, which is acquired from the tag manager 222 in real time in the database 224, and stores even environment provided after analysis in the database 224. In this case, the environment information is preferably accumulated and stored in the database 224 according to the types of PCBs and processes . For example, when the type of the PCB is PCB A, the information of the amount of water used in the cleaning process of the PCB A and the information of the turbidity of the water are stored together .

The environment application manager 225 analyzes the environment information provided from the tag manager 222 based on the environment information according to the types of the PCBs and the processes stored in the database 224, thereby generating the optimal environment information to reduce energy consumption and minimize the fraction defective. For example, through the analyzing, the optimal environment information including estimation information of time to exchange water is generated based on the information of the temperature related to a conveyer speed, the information of power consumption related to fraction defective, and the detection information of the amount of used water related to the turbidity representing the minimum fraction defective in each PCB type.

The optimal environment information is transmitted to the environment information providing unit 230, and the environment information providing unit 230 displays the optimal environment information on a screen, so that a user may easily acquire the optimal environment information according to the types of the PCBs and the processes.

The user recognizes the conveyer speed and the temperature of the drying machine representing the minimum fraction defective and the maximum production of PCBs while saving energy based on the optimal environment information provided through the environment information providing unit 230. Thereafter, the user manually sets up the optimal conveyer speed and the optimal temperature through the environment setting unit 240 serving as an input unit.

The conveyer speed value and the temperature setting value set by the user are transmitted to the environment information generation unit 220, and transmitted to a main controller to control the production facility through the communication manager 221. Accordingly, a corresponding facility is controlled based on the information of the conveyer speed and the information of the temperature of the drying machine transmitted from the main controller, so that the minimum fraction defective and the maximum production of PCBs are represented while reducing energy consumption.

As described above, according to the present invention, since the optimal energy information (environment information) in the PCB production process can be provided to a user, the user can reflect the optimal energy information when rationally calculating the production cost, reducing energy consumption, and rationally adjusting energy in each process, so that the increase in the production of PCBs and the cost reduction can be made.

Although a preferred embodiment of the present invention has been described for illustrative purposes, those skilled in the art will appreciate that various modifications, additions and substitutions are possible, without departing from the scope and spirit of the invention as disclosed in the accompanying claims.

What is claimed is:

1. A system for reducing energy consumption and fraction defective when producing a printed circuit board (PCB) based on a ubiquitous sensor network (USN), the system comprising:
a sensor node unit provided in a production facility for the PCB to acquire environment information of the production facility and wirelessly transmit the acquired environment information;
a data collection unit to collect the environment information transmitted from the sensor node unit and transmit the collected environment information through an Internet standard protocol (TCP/IP);
an environment information generation unit to receive the environment information transmitted from the data collection unit through the TCP/IP, accumulate and store the received environment information according to types of PCBs and production facilities, analyze environment information based on the accumulated environment information, such that optimal environment information is generated to reduce the energy consumption and minimize the fraction defective; and
an environment information providing unit to form the optimal environment information, which is generated from the environment information generation unit, as information to be recognized by a user and display the information to be recognized by the user.

2. The system of claim 1, wherein the sensor node unit comprises a first sensor node to acquire environment information of a cleaning machine, which is used in a cleaning process, among the production facilities for the PCB.

3. The system of claim 2, wherein the sensor node unit comprises a second sensor node to acquire environment information of a drying machine, which is used in a drying process, among the production facilities for the PCB.

4. The system of claim 2, wherein the sensor node unit comprises a third sensor node to acquire environment information of an inspecting machine, which is used in an inspecting process, among the production facilities for the PCB.

5. The system of claim 2, wherein the sensor node unit comprises a fourth sensor node to acquire environment information of a conveyer facility to transfer a PCB to be produced in the cleaning process, the drying process, and the inspecting process.

6. The system of claim 2, wherein the first sensor node comprises:
a sensor unit comprising an inverter to measure an amount of water used in the cleaning machine and a hydraulic pressure of the water and a turbidimeter to measure turbidity of the water used in the cleaning machine;
a storage unit to store an identification address used to identify the cleaning machine and store information of an amount of the used water, a hydraulic pressure of the water, and turbidity of the water which are measured; and
a communication unit to insert the identification address, which is stored in the storage unit, into a header of a packet and insert the information of the amount of the used water, the hydraulic pressure of the water, and the turbidity of the water into a specific position of the packet to form the packet and wirelessly transmit the packet.

7. The system of claim 3, wherein the second sensor node comprises:
a sensor unit comprising a watt-hour meter to measure the amount of electric power consumed by the drying machine and a thermometer to measure a temperature of the drying machine;
a storage unit to store an identification address to identify the drying machine and store information of the amount of consumed electric power and a temperature that are measured; and
a communication unit to insert the identification address, which is stored in the storage unit, into a header of a packet and insert information of the consumed electric power and the temperature into a specific position of the packet to form the packet and wirelessly transmit the packet.

8. The system of claim 4, wherein the third sensor node comprises:
a sensor unit comprising a production detection unit cooperating with the inspection machine to measure the production of the PCB and a defect inspection unit cooperating with the inspection machine to measure the fraction defective;
a storage unit to store an identification address to identify the inspecting machine and store information of the production of the PCB and the fraction defective that are measured; and
a communication unit to insert the identification address, which is stored in the storage unit, into a header of a packet and insert information of the production of the PCB and information of the fraction defective into a specific position of the packet to form the packet and wirelessly transmit the packet.

9. The system of claim 5, wherein the fourth sensor node comprises:
a sensor unit comprising a wattmeter to measure the amount of electric power consumed by the conveyer facility and a speedometer to measure a speed of the conveyer facility;
a storage unit to store an identification address to identify the conveyer facility and store information of the amount of consumed electric power and the speed of the conveyer facility that are measured; and
a communication unit to insert the identification address, which is stored in the storage unit, into a header of a packet and insert the information of the amount of consumed electric power and the speed of the conveyer facility into a specific position of the packet to form the packet and wirelessly transmit the packet.

10. The system of claim 1, wherein the data collection unit is implemented in a form of a machine-to-machine (M2M) device.

11. The system of claim 1, wherein the environment information generation unit comprises a middle-ware (M/W), and the middle-ware comprises:
a communication manager to collect the environment information in each process when producing the PCB through the data collection unit in real time;
a tag manager serving as a real-time interface with respect to the environment information acquired from the communication manager;
a real-time data manager to store the environment information, which is acquired from the tag manager in real time, in a database, and store even environment information, which is provided after analysis, in the database; and
an environment application manager to generate optimal environment information to reduce energy consumption and minimize fraction defective by analyzing the environment information provided from the tag manager according to the types of the PCBs and the production facilities.
